(19) United States
(12) Patent Application Publication
(10) Pub. No.: US 2013/0220418 A1
(43) Pub. Date: Aug. 29, 2013

(54) SEALING MATERIAL FOR PHOTOVOLTAIC CELL AND PHOTOVOLTAIC CELL ASSEMBLY

(71) Applicants: Patricia HEIDTMAN, Farmington Hills, MI (US); Eric Medaris, Grosse Pointe Woods, MI (US)

(72) Inventors: Patricia HEIDTMAN, Farmington Hills, MI (US); Eric Medaris, Grosse Pointe Woods, MI (US)

(73) Assignee: SIKA TECHNOLOGY AG, Baar (CH)

(21) Appl. No.: 13/406,146

(22) Filed: Feb. 27, 2012

(51) Int. Cl. H01L 31/0203; B32B 3/30

(52) U.S. Cl. 136/259; 428/172

(57) ABSTRACT

A sealing material suitable for sealing a juncture between an edge of a photovoltaic cell and a frame for accommodating the photovoltaic cell, the sealing material including: a physical locking layer comprising a plurality of flexible protrusions extending from a surface of the physical locking layer; and an adhesive layer comprising an adhesive surface for attaching the sealing material to the edge of the photovoltaic cell; wherein the sealing material has an elongated shape, wherein the sealing material is capable of forming a friction fit between the plurality of flexible protrusions and a surface of the frame when the sealing material is disposed at the juncture between the edge of the photovoltaic cell and the frame for accommodating the photovoltaic cell.

### FIELD

The present disclosure relates to a sealing material for use with a photovoltaic cell. The present disclosure also relates to a sealed photovoltaic cell assembly formed with a sealing material, and a photovoltaic cell-frame assembly formed with a sealing material.

### BACKGROUND INFORMATION

Photovoltaic cells can be exposed to varying degrees of moisture during operation. Moisture infiltrating into the photovoltaic cell can adversely affect the performance and durability of the photovoltaic cell. An edge of the photovoltaic cell can be sealed in order to provide moisture resistance.

The edge of the photovoltaic cell can be sealed with a double-sided, self-adhesive foam tape formed from a polyolefin elastomeric foam. One side of the double-sided adhesive can be used to attach the tape to the photovoltaic cell, and the other side of the double-sided adhesive can be used to attach the tape to a frame for holding the photovoltaic cell.

### SUMMARY

According to an exemplary aspect, disclosed is a sealing material suitable for sealing a juncture between an edge of a photovoltaic cell and a frame for accommodating the photovoltaic cell, the sealing material comprising: a physical locking layer comprising a plurality of flexible protrusions extending from a surface of the physical locking layer; and an adhesive layer comprising an adhesive surface for attaching the sealing material to the edge of the photovoltaic cell; wherein the sealing material has an elongated shape, wherein the sealing material is capable of forming a friction fit between the plurality of flexible protrusions and a surface of the frame when the sealing material is disposed at the juncture between the edge of the photovoltaic cell and the frame for accommodating the photovoltaic cell.

According to an exemplary aspect, disclosed is a photovoltaic cell and sealing material assembly, the assembly comprising: a photovoltaic cell; and a sealing material comprising: a physical locking layer comprising a plurality of flexible protrusions extending from a surface of the physical locking layer; and an adhesive layer comprising an adhesive surface for attaching the sealing material to an edge of the photovoltaic cell; wherein the sealing material has an elongated shape; wherein the sealing material is attached to the edge of the photovoltaic cell.

According to an exemplary aspect, disclosed is a photovoltaic cell and frame assembly, the assembly comprising: a photovoltaic cell; a frame comprising an elongated channel for accommodating an edge of the photovoltaic cell; and a sealing material comprising: a physical locking layer comprising a plurality of flexible protrusions extending from a surface of the physical locking layer; and an adhesive layer comprising an adhesive surface for attaching the sealing material to the edge of the photovoltaic cell; wherein the sealing material has an elongated shape; wherein the sealing material is disposed in the elongated channel of the frame; wherein the sealing material forms a friction fit between the plurality of flexible protrusions and a surface of the frame.

According to an exemplary aspect, disclosed is a method of sealing a juncture between an edge of a photovoltaic cell and a frame, the method comprising: attaching a sealing material to an edge of a photovoltaic cell; providing a frame comprising an elongated channel for accommodating the photovoltaic cell; and inserting at least a portion of the edge of the photovoltaic cell to which the sealing material is attached, into the elongated channel of the frame.

According to an exemplary aspect, disclosed is a method of installing a photovoltaic cell into a frame, the method comprising inserting at least a portion of an edge of the photovoltaic cell and sealing material assembly into an elongated channel of a frame.

### BRIEF DESCRIPTION OF THE DRAWINGS

FIG. 1 is a cross-sectional view of an exemplary sealing material, in accordance with an exemplary aspect.

FIG. 2 is a cross-sectional view of an exemplary sealing material-photovoltaic cell assembly inserted into a frame, in accordance with an exemplary aspect.

FIG. 3 is a cross-sectional view of an exemplary sealing material-photovoltaic cell assembly inserted into a frame, in accordance with an exemplary aspect.

FIG. 4 is a cross-sectional view of an exemplary sealing material, in accordance with an exemplary aspect.

FIG. 5 is a cross-sectional view of an exemplary sealing material-photovoltaic cell assembly inserted into a frame, in accordance with an exemplary aspect.

FIG. 6 is a cross-sectional view of an exemplary sealing material, in accordance with an exemplary aspect.

FIG. 7 illustrates various exemplary cross-sectional shapes of the flexible protrusions of the sealing material, in accordance with an exemplary aspect.

FIG. 8 is a cross-sectional view of an exemplary sealing material-photovoltaic cell assembly inserted into a frame, in accordance with an exemplary aspect. Such figure is discussed in the examples.

### DETAILED DESCRIPTION

According to an exemplary embodiment, a sealing material is provided that is suitable for sealing a joint between an edge of a photovoltaic cell and a frame for accommodating the photovoltaic cell. For example, the sealing material can seal the edge of a photovoltaic cell so as to reduce or prevent moisture and/or gas permeation into the layers of the photovoltaic cell and/or the channel of the frame. The sealing material can also allow a sealing material-photovoltaic cell assembly to be secured to and removed from a frame, for example, by a friction fit in the frame channel. The sealing material-photovoltaic cell assembly can be secured to the frame by the friction fit alone or in combination with, for example, an adhesive. In an exemplary embodiment, the use of an adhesive between the assembly and the frame to lock the assembly to the frame, can be reduced or eliminated. The sealing material can facilitate removal of the assembly from the frame, for example, in the case of maintenance or replacement of the photovoltaic cell.

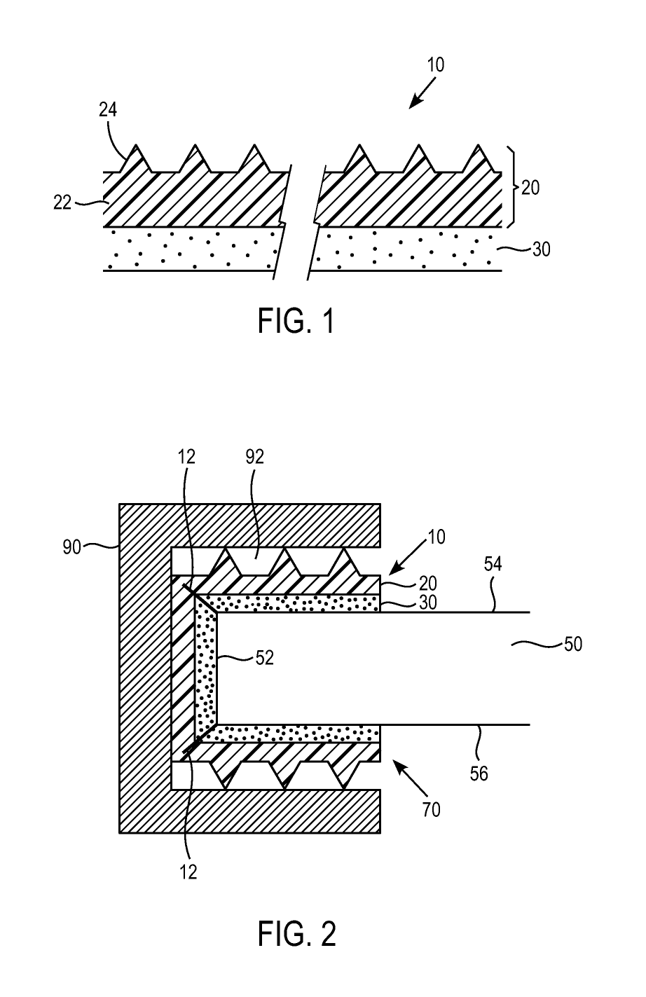

Referring to FIG. 1, an exemplary sealing material 10 can include a physical locking layer 20 and an adhesive layer 30. The adhesive layer 30 can be in direct contact with the physical locking layer 20, or at least one additional layer (not shown) can be present in between the physical locking layer 20 and the adhesive layer 30. In an exemplary embodiment, the adhesive layer 30 can be in direct contact with the physical locking layer 20. The adhesive layer 30 can also provide a moisture barrier function by sealing an edge of a photovoltaic cell.

Referring to FIG. 2, the sealing material 10 can be capable of wrapping around an edge 52 of the photovoltaic cell 50. The adhesive layer 30 of the sealing material 10 can adhere to an upper surface 54 and a lower surface 56 of the photovoltaic cell 50 to maintain the wrapped configuration of the sealing material 10. The sealing material 10 can be sufficiently flexible to allow for such wrapping around the edge 52 of the photovoltaic cell 50. For example, the sealing material can include lines of weakness 12 such as incisions or voids which facilitate the bending and/or folding of the sealing material 10.

The physical locking layer 20 can be the outermost layer of the sealing material 10. For example, the physical locking layer 20 can have a substantially exposed surface prior to installation of the sealing material-photovoltaic cell assembly 70 into a frame 90. The adhesive layer 30 can be the innermost layer of the sealing material 10. For example, the adhesive layer 30 can have a substantially exposed surface prior to attaching the sealing material 10 to the photovoltaic cell 50. Once the sealing material 10 is attached to the photovoltaic cell 50, the resulting assembly 70 can be inserted into a channel 92 of the frame 90.

The physical locking layer 20 can form a barrier to water in liquid and/or vapor form, when placed in contact with the frame 90. For example, when the sealing material 10 is applied to an edge 52 of the photovoltaic cell 50, and the sealing material-photovoltaic cell assembly 70 is inserted into the frame 90, the physical locking layer 20 can contact the inner surface of the frame 70 in a manner which forms a water-tight seal between the physical locking layer 20 and the inner surface of the frame 90.

The physical locking layer 20 can include a base layer 22 and a plurality of flexible protrusions 24 extending from the base layer 22. The base layer 22 and the plurality of flexible protrusions 24 can be formed from the same, integrated material such as, for example, from an extrusion process. Alternatively, the plurality of flexible protrusions 24 can be formed from a separate material and attached to the base layer 22. The plurality of flexible protrusions 24 can extend from the outer surface of the physical locking layer 20.

The plurality of flexible protrusions can be located on the side of physical locking layer that is opposite the side of the physical locking layer that is nearest to the adhesive layer. This can enable the flexible protrusions to be available to engage a channel of a frame for accommodating the sealing material-photovoltaic cell assembly.

The plurality of flexible protrusions can have an arrangement, shape and dimensions which enable such plurality of flexible protrusions to form a water barrier when in contact with the frame. The arrangement, shape and dimensions of the plurality of flexible protrusions can also enable the physical locking layer to form a friction fit between the plurality of flexible protrusions and a surface of the frame, for example, when the sealing material is attached to the photovoltaic cell. For example, the physical locking layer can allow the edge of the photovoltaic cell to be secured to the frame without the use of an adhesive between the physical locking layer and the frame surface. In an exemplary embodiment, the sealing material-photovoltaic cell assembly can be securely installed in the frame with the physical locking layer being in direct contact with the surface of the frame. In an alternative embodiment, an adhesive can be used to adhere a portion of the physical locking layer, for example a portion of the physical locking layer that does not have any flexible protrusions, to the frame.

The flexible protrusions of the sealing material can allow for coefficient of thermal expansion (CTE) management of the frame and the photovoltaic cell. For example, in the case where the frame and photovoltaic cell are made of different materials (for example the frame is made from aluminum and the photovoltaic cell contains a glass backing), a CTE differential exists between such materials, and such materials can undergo thermal expansion and contraction at different rates. The flexible protrusions can allow for relative movement between the photovoltaic cell and the frame, while still providing an adequate degree of physical locking or friction fit.

The arrangement, shape and dimensions of the plurality of flexible protrusions can depend, for example, on the dimensions of the photovoltaic cell, the dimensions of the channel of the frame, and the materials employed.

The height of the flexible protrusions can depend on, for example, the shape of the protrusions, the number of protrusions, the overall thickness of the sealing material, the width of the frame channel, and the materials and thermal expansion characteristics of the frame and photovoltaic cell. For example, the height of the flexible protrusions can be set to allow for relative movement between the frame and photovoltaic cell due to thermal expansion and contraction, while at the same time maintaining physical locking characteristics.

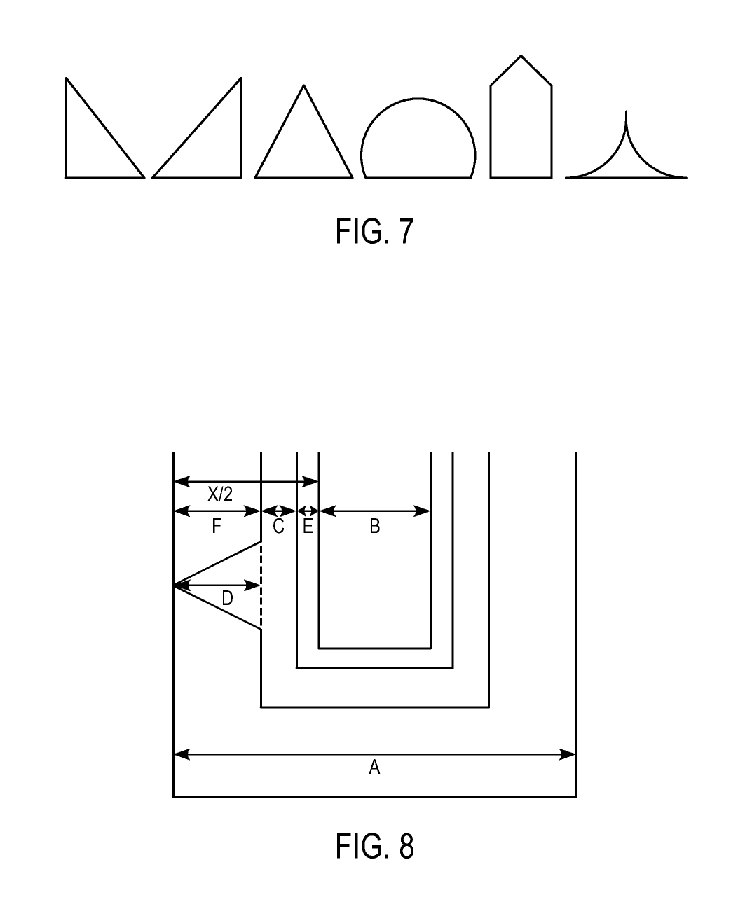

The flexible protrusions can have any suitable shape. For example, the flexible protrusions can have a shape which enables such flexible protrusions to achieve physical locking and a friction fit with the frame. For example, the flexible protrusions can have a cross-sectional profile having a triangular shape, a square or rectangular shape, a pentagonal shape, a rounded shape, a partially circular shape, and/or a parabolic shape. One or more shapes can be employed. The triangular shape can include an equilateral triangle, an isosceles triangle, or a right triangle. Exemplary cross-sectional profiles of the flexible protrusions are shown in FIG. 7.

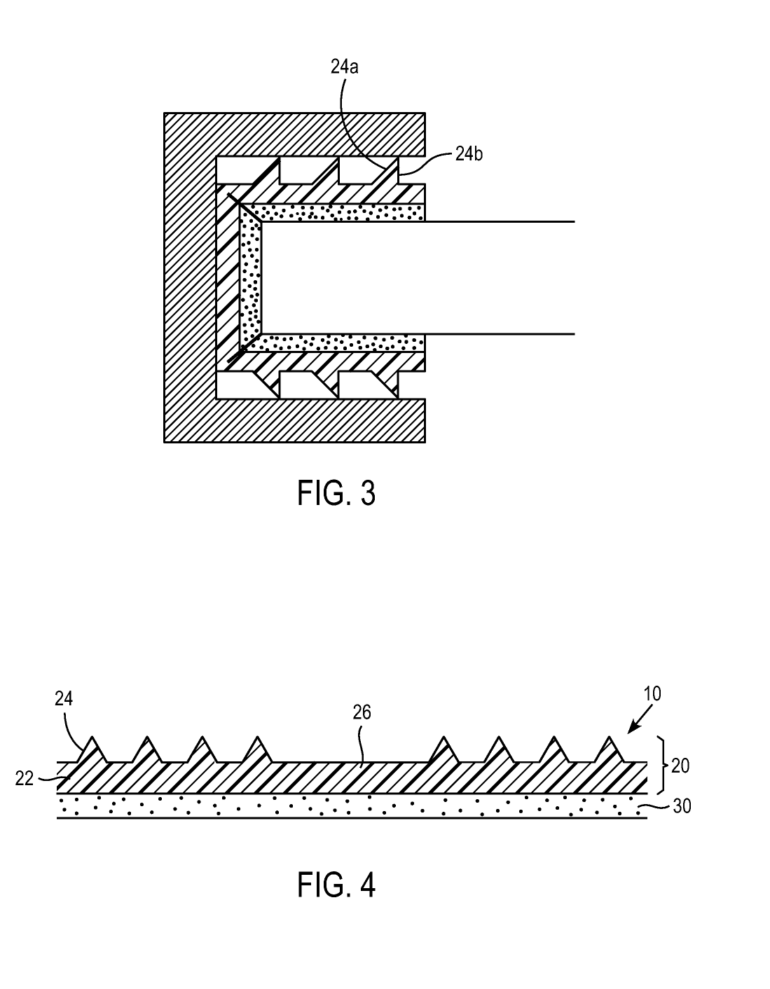

In an exemplary embodiment, the flexible protrusions can have a right triangle shaped cross-sectional profile. For example, as can be seen from FIG. 3, the right triangles can be oriented such that when the sealing material-photovoltaic cell assembly is inserted into the frame, the sloped side 24a (i.e., the hypotenuse) of the triangle-shaped protrusions contacts the surface of the frame and facilitates insertion of the assembly into the frame. The right-angled side 24b of the triangle-shaped protrusions can facilitate the friction fit of the sealing material and reduce or prevent unintended movement of the assembly.

The number of flexible protrusions per unit length and the arrangement of such flexible protrusions can depend on, for example, the width of the frame channel, the width of the photovoltaic cell, the thicknesses of the physical locking and adhesive layers. For example, the number of flexible protrusions per unit length and the arrangement of such flexible protrusions can be set such that the sealing material accommodates thermal expansion and contraction of the frame and cell while maintaining physical locking characteristics. For example, the number of protrusions per unit length may be inversely proportional to the height of the protrusions. In an exemplary embodiment, the flexible protrusions can be arranged in a substantially uniform manner, for example, spaced apart in substantially uniform intervals.

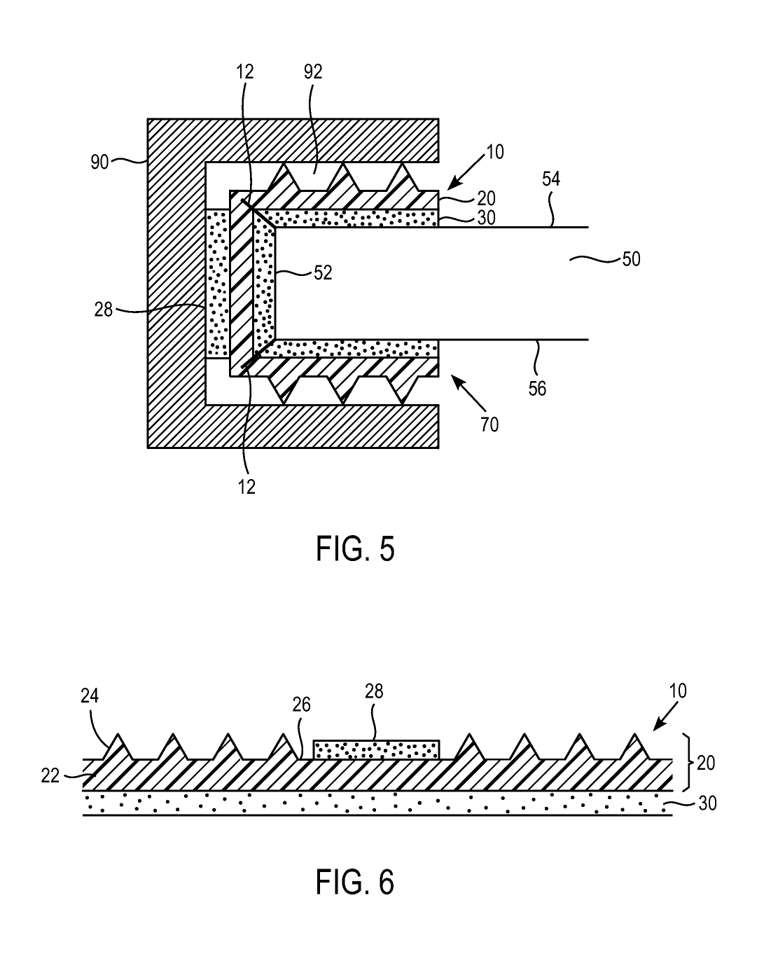

Referring to FIG. 4, in an exemplary embodiment, a central portion 26 of the physical locking layer 20 can be provided which extends in a lengthwise direction of the sealing material 10, and which can be free of flexible protrusions. In such exemplary embodiment, the flexible protrusions 24 can be arranged in a substantially uniform manner in areas other than the central portion 26. The central portion 26 can accommodate the inner surface of the frame when the sealing material-photovoltaic cell assembly is inserted into the frame. For example, the central portion 26 can be in direct contact with the inner surface of the frame 90, as can be seen in FIG. 2. In an alternative embodiment shown in FIGS. 5 and 6, the central portion can have an adhesive 28 disposed thereon. The adhesive 28 can attach the central portion 26 to the inner surface of the frame. The adhesive 28 can be selected from materials used to form the adhesive layer 30, and can have a thickness selected from the thickness range of the adhesive layer 30. The width of the central portion that is free of flexible protrusions can depend on, for example, the thickness of the photovoltaic cell (for example, the length of the edge surface of the cell). In an exemplary embodiment, the central portion that is free of flexible protrusions can have a width of about 0 to about 3.0 cm, for example, from about 0.2 to about 2.5 cm, for example, from about 0.5 to about 1.5 cm. For example, the central portion that is free of flexible protrusions can have a width that is about 20% to about 60%, for example, from about 30% to about 50%, of the total width of the sealing material. The adhesive, if present, can have the same width as or a smaller width than the width of the central portion that is free of flexible protrusions.

The material used to form the physical locking layer can allow such layer to provide a physical locking function. For example, the material can allow the physical locking layer to form a friction fit between the plurality of flexible protrusions and a surface of the frame, for example, when the sealing material is attached to the photovoltaic cell. The physical locking layer can have temperature and humidity resistance properties which allow for its use in indoor and outdoor applications. For example, the physical locking layer can be formed from a flexible, UV-stable polymer. For example, the physical locking layer can be formed from thermoplastic vulcanizates, PVC, TPV (for example, medium to high hardness grade TPV), TPE (for example, PVC), TPO, a water swellable polymer, (for example, Hydrotite®), or a combination thereof. For example, the physical locking layer can be formed from a polypropylene based elastomer, Sarlink™ X-5775B4, available from DSM Thermoplastic Elastomers B.V. For example, the physical locking layer can be formed from a thermally reactive thermoplastic, for example, ethylene vinyl acetate copolymer, ethylene block copolymer, and/or low density polyethylene. The plurality of flexible protrusions can be formed from the same material as or a different material from, the base layer of the physical locking layer.

In an exemplary embodiment, the plurality of flexible protrusions (or the entire physical locking layer) do not include an overly rigid thermoplastic material. For example, the plurality of flexible protrusions (or the entire physical locking layer) can be formed from a material having an elongation at break of about 200 to 1000%, for example, from about 450 to 650%. For example, the plurality of flexible protrusions (or the entire physical locking layer) can be formed from a material having a Shore A hardness of about 20 to 90, for example, from about 60 to 80.

When the sealing material-photovoltaic cell assembly is inserted into the frame channel, the average height of the flexible protrusions can be equal to or exceed the gap between the base layer of the sealing material and the channel surface. For example, the average height of the flexible protrusions can be about 100% to about 250% of the width of the gap between the base layer of the sealing material and the channel surface, for example, from about 125% to about 225%, for example, from about 150% to about 200%. For example, the height of the flexible protrusions can be from about 20% to about 40% of the overall thickness of the sealing material.

The thickness of the base layer and the height of the flexible protrusions can depend on, for example, the width of the gap between the frame wall and photovoltaic cell when the photovoltaic cell assembly is inserted into the frame. For example, the thickness of the base layer can be from about 40% to about 80% of the gap between the frame wall and photovoltaic cell, for example, from about 50% to about 70%, for example, from about 55% to about 65%. For example, the height of the flexible protrusions can be from about 10% to about 90% of the gap between the frame wall and photovoltaic cell, for example, from about 20% to about 80%, for example, from about 25% to about 70%.

The thickness of the physical locking layer can depend on, for example, the material used to form the physical locking layer, the thickness of the adhesive layer, and the width of the channel of the frame. For example, the thickness of the physical locking layer, measured from the average height of the peaks of the flexible protrusions to the surface of the base layer which faces the adhesive layer, can be from about 0.3 mm to about 2.5 mm, for example, from about 0.4 mm to about 2 mm, for example, from about 0.5 mm to about 1.5 mm. For example, the average thickness of the flexible protrusions can be from about 0.2 mm to about 1 mm, for example, from about 0.3 mm to about 0.5 mm. For example, the average thickness of the base layer can be from about 0.2 mm to about 1.5 mm, for example, from about 0.4 to about 0.9 mm.

The adhesive layer can be employed to attach the sealing material to the edge of the photovoltaic cell. The adhesive layer can directly contact at least one surface of the photovoltaic cell, for example, at least an upper surface and a lower surface of the photovoltaic cell, for example, at least the upper surface, lower surface and an edge surface of the photovoltaic cell. By attaching to at least the upper and lower surfaces of the photovoltaic cell, for example, the adhesive layer can secure the sealing material to the edge of the photovoltaic cell.

A first portion of the adhesive layer can adhere to an upper surface of the photovoltaic cell, and a second portion of the adhesive layer can adhere to a lower surface of the photovoltaic cell. A third portion of the adhesive layer can adhere to the edge surface of the photovoltaic cell. In an exemplary embodiment, the adhesive layer can include the first and second portions for adhering to the upper and lower surfaces of the photovoltaic cell, and does not include a third portion for adhering to the edge surface of the photovoltaic cell.

The adhesive layer can be formed from any material, for example, that is suitable for adhering to a frame material and the physical locking layer. The adhesive layer can have temperature and humidity resistance properties which allow for its use in indoor and outdoor applications. The adhesive layer can function as a moisture barrier. For example, the adhesive layer can seal the edge of the photovoltaic cell, reducing the amount of moisture (or preventing moisture) from contacting the edge of the photovoltaic cell. For example, a flexible, UV stable polymer can be used. For example, the adhesive layer can include a polyisobutylene/isoprene copolymer, EPDM, butyl, acrylic, or a combination thereof.

The thickness of the adhesive layer can depend on, for example, the width of the gap between the frame wall and photovoltaic cell when the photovoltaic cell assembly is inserted into the frame. For example, the thickness of the adhesive layer can be from about 1% to about 50% of the gap between the frame wall and photovoltaic cell, for example, from about 15% to about 50%, for example, from about 20% to about 30%.

The thickness of the adhesive layer can depend on, for example, the material used to form the adhesive layer, the thickness of the physical locking layer, and the width of the channel of the frame. For example, the thickness of the adhesive layer can be from about 0.1 mm to about 1 mm, for example, from about 0.3 mm to about 0.8 mm, for example, from about 0.5 mm to about 0.7 mm.

The sealing material can include a backing material which protects the adhesive layer during storage and transport. For example, when the sealing material is ready to be applied, the backing material can be separated from the adhesive layer by, for example, peeling, to expose the adhesive surface.

The sealing material can have an elongated shape. For example, the sealing material can be in the form of a tape, and the sealing material can be rolled into a coil arrangement to facilitate storage and transport. The materials used to form the sealing material can be sufficiently flexible so as to allow the sealing material to be rolled into the coil arrangement. The width of the sealing material can depend on, for example, the dimensions of the photovoltaic cell and the frame. The sealing material can have a width of, for example, from about 10 to about 50 mm, for example, from about 12 mm to about 26 mm, for example, about 25 mm.

The thickness of the sealing material can depend on, for example, the width of the channel frame and the thickness of the photovoltaic cell. For example, the sealing material can have a thickness of, for example, from about 0.3 mm to about 3 mm, for example, from about 0.5 mm to about 2.0 mm, for example, from about 0.6 mm to about 1.5 mm, for example, from about 0.8 to about 1.1 mm. The thickness of the sealing material is measured from the average peak of the flexible protrusions to the outermost surface of the adhesive layer.

The physical locking layer of the sealing material can have properties, for example, for facilitating its use as a sealant of a photovoltaic cell. For example, the physical locking layer can have a tensile strength of about 0.5 MPa or more, for example, about 1 MPa or more. For example, the physical locking layer can have an elongation at break characteristic of greater than about 200%, for example, greater than about 300%. For example, the physical locking layer can have a peel adhesion characteristic of about 3 MPa or more, for example, about 5 MPa or more. For example, the physical locking layer can be resistant to temperatures of at least 85° C., for example, at least 100° C. For example, the physical locking layer can be resistant to UV light and glass cleaning agents. For example, the physical locking layer can be compliant with IEC 61212/61646 and UL 94 HB.

According to another exemplary aspect, a sealing material-photovoltaic cell assembly is provided. The assembly can be produced by attaching the sealing material to at least one edge of a photovoltaic cell, for example, at least two edges of the photovoltaic cell, for example, at least three edges of the photovoltaic cell, for example, at least four edges of the photovoltaic cell.

According to another exemplary aspect, a photovoltaic cell-frame assembly is provided. The assembly can be produced by inserting at least a portion of one edge of the sealing material-photovoltaic cell assembly into a channel of frame, for example, at least two edges of the assembly, for example, at least three edges of the assembly, for example, at least four edges of the assembly.

The sealing material can be produced by any suitable method. For example, the starting material for the physical locking layer can be extruded into a desired profile having the flexible protrusions using an extruder such as, for example, a single screw extruder. The profile can be obtained using a profiled die at the end of the extruder. The material for forming the adhesive layer can be present in the form of an adhesive composition which can be applied to the material for forming the physical locking layer during or after the extrusion process. For example, the adhesive composition can be applied after the material for forming the physical locking layer has been subjected to a cooling process. The adhesive composition can be applied by any suitable process including, for example, by painting, for example, by a roller, for example, in an inline process wherein the adhesive composition is at an elevated temperature. In an alternative embodiment, the adhesive can be applied by pressure application of a cold adhesive strip. The material for forming the adhesive layer can be co-extruded with the material for forming the physical locking layer.

The sealing material can be applied to a photovoltaic cell and installed in a frame by any suitable method. For example, the sealing material can be attached to an edge of a photovoltaic cell. A frame including an elongated channel for accommodating the photovoltaic cell can be provided. At least a portion of the edge of the sealing material-photovoltaic cell assembly can be inserted into the elongated channel of the frame.

For example, the sealing material can be applied to an edge of the photovoltaic cell, for example, before final module assembly. For example, the sealing material can be suitable for use during photovoltaic cell module manufacture due to the ease of its application. In an exemplary embodiment, the method of affixing the sealing material to the photovoltaic cell assembly does not include the use of a pumped silicone or a hot-melt sealant. The sealing material can be rolled over the edge of the photovoltaic cell using a rolling tool either manually by hand or using an automated process. The sealing material-photovoltaic cell assembly can be inserted into the channel of the frame.

The photovoltaic cell can have any suitable size and dimensions, and the characteristics of the sealing material can be adjusted to be adapted for use with the specific size of the photovoltaic cell. For example, the photovoltaic cell is one that is capable of being held in place by a frame for accommodating such a cell. The photovoltaic cell includes at least one edge, for example, a plurality of edges which can be inserted into the frame. The photovoltaic cell can be formed from any suitable material, for example, a material that allows for the conversion of the energy of light into electricity. For example, the exterior, large surfaces of the photovoltaic cell (i.e., the upper and lower surfaces) can be made of glass, TPT (tedlar/polyester/tedlar), TPE (tedlar/polyester/EVA), FPE (fluorinated polyester), PPE (polyphenylene ethynylene), polyester, PLA (polylactic acid resin), and/or nylon 11. In an exemplary embodiment, the edges of the photovoltaic cell can be the exposed edges of the various laminates which form the photovoltaic cell.

The frame can have a shape which accommodates at least one edge of the photovoltaic cell. For example, the frame can have a channel such as, for example, a U-shaped channel. Any suitable material can be employed for forming the frame. For example, the frame can be formed from aluminum such as anodized aluminum, and/or steel such as stainless steel.

### EXAMPLES

Disclosed are non-limiting examples of sealing materials. From the examples, it can be seen that the dimensions of the sealing material, flexible protrusions, base layer and adhesive layer can vary depending on the thickness of the channel of the frame. The dimensions of the constituents of the sealing material can also vary depending on the thickness of the photovoltaic cell. The examples are set forth in Table 1, wherein the dimensions referred in Table 1 are shown in FIG. 8.

TABLE 1
Dimensions of Exemplary Sealing Materials

| | Example No. | | | | | |
|---|---|---|---|---|---|---|
| | 1 | 2 | 3 | 4 | 5 | 6 |
| Width of channel of | 6.35 | 7 | 8 | 6.35 | 7 | 8 |
| frame, A (mm) | | | | | | |
| Thickness of | 5 | 5 | 5 | 5 | 5 | 5 |
| photovoltaic cell, B (mm) | | | | | | |
| Total gap in channel, X | 1.35 | 2 | 3 | 1.35 | 2 | 3 |
| (mm) | | | | | | |
| Gap between channel | 0.675 | 1 | 1.5 | 0.675 | 1 | 1.5 |
| wall and photovoltaic | | | | | | |
| cell, X/2 (mm) | | | | | | |
| Thickness of adhesive | 0.075 | 0.1 | 0.15 | 0.075 | 0.1 | 0.15 |
| layer, E (mm) | | | | | | |
| Thickness of base layer, | 0.4 | 0.6 | 0.9 | 0.4 | 0.6 | 0.9 |
| C (mm) | | | | | | |
| Height of flexible | 0.2 | 0.3 | 0.45 | 0.3 | 0.45 | 0.675 |
| protrusion, D (mm) | | | | | | |
| Total thickness of | 0.675 | 1.0 | 1.5 | 0.775 | 1.15 | 1.725 |
| sealing material | | | | | | |
| (i.e., E + C + D) (mm) | | | | | | |
| Gap between channel | 0.2 | 0.3 | 0.45 | 0.2 | 0.3 | 0.45 |
| wall and base layer, F | | | | | | |
| (i.e., X/2 − C + E) (mm) | | | | | | |
| Ratio of height of flexible | 100% | 100% | 100% | 150% | 150% | 150% |
| protrusion, to gap | | | | | | |
| between channel wall | | | | | | |
| and base layer | | | | | | |
| (i.e., D/F) | | | | | | |

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. A sealing material suitable for sealing a juncture between an edge of a photovoltaic cell and a frame for accommodating the photovoltaic cell, the sealing material comprising:
a physical locking layer comprising a plurality of flexible protrusions extending from a surface of the physical locking layer; and
an adhesive layer comprising an adhesive surface for attaching the sealing material to the edge of the photovoltaic cell;
wherein the sealing material has an elongated shape,
wherein the sealing material is capable of forming a friction fit between the plurality of flexible protrusions and a surface of the frame when the sealing material is disposed at the juncture between the edge of the photovoltaic cell and the frame for accommodating the photovoltaic cell.

2. The sealing material of claim 1, wherein the average height of the plurality of flexible protrusions is from about 20% to about 40% of the overall thickness of the sealing material.

3. The sealing material of claim 1, wherein the plurality of flexible protrusions have a triangle-shaped cross-sectional profile.

4. The sealing material of claim 1, wherein the physical locking layer comprises a central portion which extends in a lengthwise direction of the sealing material, wherein the central portion is free of flexible protrusions.

5. The sealing material of claim 1, wherein the thickness of the sealing material is about 0.8 to about 1.1 mm.

6. A photovoltaic cell and sealing material assembly, the assembly comprising:
a photovoltaic cell; and
a sealing material comprising:
a physical locking layer comprising a plurality of flexible protrusions extending from a surface of the physical locking layer; and
an adhesive layer comprising an adhesive surface for attaching the sealing material to an edge of the photovoltaic cell;
wherein the sealing material has an elongated shape;
wherein the sealing material is attached to the edge of the photovoltaic cell.

7. The photovoltaic cell and sealing material assembly of claim 6, wherein the average height of the plurality of flexible protrusions is from about 20% to about 40% of the overall thickness of the sealing material.

8. The photovoltaic cell and sealing material assembly of claim 6, wherein the plurality of flexible protrusions have a triangle-shaped cross-sectional profile.

9. The photovoltaic cell and sealing material assembly of claim 6, wherein the physical locking layer comprises a central portion which extends in a lengthwise direction of the sealing material, wherein the central portion is free of flexible protrusions.

10. The photovoltaic cell and sealing material assembly of claim 6, wherein the thickness of the sealing material is about 0.8 to about 1.1 mm.

11. A photovoltaic cell and frame assembly, the assembly comprising:
a photovoltaic cell;
a frame comprising an elongated channel for accommodating an edge of the photovoltaic cell; and
a sealing material comprising:
a physical locking layer comprising a plurality of flexible protrusions extending from a surface of the physical locking layer; and
an adhesive layer comprising an adhesive surface for attaching the sealing material to the edge of the photovoltaic cell;
wherein the sealing material has an elongated shape;
wherein the sealing material is disposed in the elongated channel of the frame;
wherein the sealing material forms a friction fit between the plurality of flexible protrusions and a surface of the frame.

12. The photovoltaic cell and frame assembly of claim 11, wherein the average height of the plurality of flexible protrusions is from about 20% to about 40% of the overall thickness of the sealing material.

13. The photovoltaic cell and frame assembly of claim 11, wherein the plurality of flexible protrusions have a triangle-shaped cross-sectional profile.

14. The photovoltaic cell and frame assembly of claim 11, wherein the physical locking layer comprises a central portion which extends in a lengthwise direction of the sealing material, wherein the central portion is free of flexible protrusions.

15. The photovoltaic cell and frame assembly of claim 11, wherein the thickness of the sealing material is about 0.8 to about 1.1 mm.

16. A method of sealing a juncture between an edge of a photovoltaic cell and a frame, the method comprising:
attaching the sealing material of claim 1 to an edge of a photovoltaic cell;
providing a frame comprising an elongated channel for accommodating the photovoltaic cell; and
inserting at least a portion of the edge of the photovoltaic cell to which the sealing material is attached, into the elongated channel of the frame.

17. The method of claim 16, wherein the average height of the plurality of flexible protrusions is from about 20% to about 40% of the overall thickness of the sealing material.

18. The method of claim 16, wherein the plurality of flexible protrusions have a triangle-shaped cross-sectional profile.

19. The method of claim 16, wherein the physical locking layer comprises a central portion which extends in a lengthwise direction of the sealing material, wherein the central portion is free of flexible protrusions.

20. The method of claim 16, wherein the thickness of the sealing material is about 0.8 to about 1.1 mm.

21. A method of installing a photovoltaic cell into a frame, the method comprising inserting at least a portion of an edge of the photovoltaic cell and sealing material assembly of claim 2 into an elongated channel of a frame.
